(19) United States
(12) Patent Application Publication
(10) Pub. No.: US 2024/0276838 A1
(43) Pub. Date: Aug. 15, 2024

(54) DISPLAY DEVICE

(71) Applicant: SAMSUNG DISPLAY CO., LTD., YONGIN-SI (KR)

(72) Inventors: HAKBUM CHOI, Yongin-si (KR); JANG-IL KIM, Yongin-si (KR); JEONGKI KIM, Yongin-si (KR); JONG-HOON KIM, Yongin-si (KR); SUJIN LEE, Yongin-si (KR)

(21) Appl. No.: 18/435,178

(22) Filed: Feb. 7, 2024

(30) Foreign Application Priority Data
Feb. 13, 2023 (KR) 10-2023-0018901

(51) Int. Cl. H10K 59/80; H10K 59/12; H10K 59/127; H10K 59/38; H10K 59/88; H10K 71/50

(52) U.S. Cl. CPC H10K 59/8722; H10K 59/1201; H10K 59/127; H10K 59/38; H10K 59/873; H10K 59/877; H10K 59/88; H10K 71/50

(57) ABSTRACT

A display device includes a first display substrate, a second display substrate, and a sealing member. The first display substrate includes a first base layer. The second display substrate includes a second base layer including pixel regions and a peripheral region, and color filters, and is disposed on the first display substrate. The sealing member is interposed between the first display substrate and the second display substrate. The first display substrate includes light emitting elements overlapped with the pixel regions, respectively, an encapsulation layer to cover the light emitting elements, a split pattern including openings overlapped with the pixel regions, respectively, and disposed on the encapsulation layer, and light control patterns disposed in the openings. An end portion of an organic layer of the encapsulation layer, which is overlapped with the non-display region, is covered by the split pattern.

### CROSS-REFERENCE TO RELATED APPLICATIONS

This U.S. patent application claims priority under 35 U.S.C. § 119 to Korean Patent Application No. 10-2023-0018901 filed on Feb. 13, 2023, in the Korean Intellectual Property Office, the disclosure of which is incorporated by reference in its entirety herein.

### 1. TECHNICAL FIELD

Embodiments of the present disclosure described herein relate to a display device, and more particularly, relate to a display device including a panel in which two display substrates are coupled to each other.

### 2. DISCUSSION OF RELATED ART

Display devices such as smartphones, digital cameras, notebook computers, navigation devices and smart televisions, provide a user with an image through a display screen. The display devices may include a display panel that generates the image.

The display device may be a transmissive display device having a display panel that uses source light generated from a light source or an emissive display device having a display panel providing self-emitted source light. The display panel may include various types of functional patterns depending on its pixels to generate an image. The functional pattern may transmit only a partial wavelength range of the source light or may convert a color of the source light.

However, the display panel may become defective when moisture penetrates from the outside and if dents occur during manufacturing. Thus, there is a need for a display device that can better prevent moisture from infiltrating and be more resilient to dents.

### SUMMARY

Embodiments of the present disclosure provide a display device that is less likely to become defective based on moisture and/or dents.

According to an embodiment, a display device includes a first display substrate, a second display substrate, and a sealing member. The first display substrate includes a first base layer which includes a display region and a non-display region adjacent to the display region, a second display substrate including a second base layer which includes pixel regions, each of which is overlapped with the display region and a peripheral region adjacent to the pixel regions, and color filters disposed on the second base layer, and spaced apart from the first display substrate. The sealing member is interposed between the first display substrate and the second display substrate and overlapped with the non-display region. The first display substrate includes light emitting elements overlapped with the pixel regions, respectively, an encapsulation layer to cover the light emitting elements, a split pattern including openings overlapped with the pixel regions, respectively, and disposed on the encapsulation layer, and light control patterns disposed in the openings. An end portion of an organic layer of the encapsulation layer overlapped with the non-display region is covered by the split pattern.

The second display substrate may further include a lower refractive layer to cover the color filters, an upper cover layer to cover the lower refractive layer, and a step difference compensating layer that covers the upper cover layer and is overlapped with the non-display region, and the sealing member may contact the step difference compensating layer and the first display substrate.

The second display substrate may further include an upper cover layer to cover the color filters, and a step difference compensating layer that covers the upper cover layer and is overlapped with the non-display region, and the sealing member may contact the step difference compensating layer and the first display substrate.

The first display substrate may further include a dummy pattern disposed in the non-display region, a material of the dummy pattern is the same as a material of one of the light control patterns, and the sealing member may be interposed between the dummy pattern and the second display substrate.

The split pattern further may include a first part disposed in the display region and a second part disposed in the non-display region and extending from the first part, and the sealing member may be interposed between the second part and the second display substrate.

The second part may include at least one pattern hole formed through the split pattern while extending from a top surface of the split pattern and a bottom surface of the split pattern, and the sealing member may be disposed inside the at least one pattern hole.

The first display substrate further may include dam patterns disposed on the first base layer and overlapped with the non-display region, a boundary of the organic layer may be defined by a first one of the dam patterns, a boundary of the split pattern may be defined by a second other one of the dam patterns, the second dam pattern is closer to the sealing member than the first dam pattern.

Each of the dam patterns may have a closed-line shape to surround the display region.

In an embodiment, the organic layer is disposed between a first inorganic layer and a second inorganic layer, and the first inorganic layer and the second inorganic layer contact each other in the non-display region and cover at least one of the dam patterns.

The first display substrate and the second display substrate may be spaced apart from each other while interposing a cell gap between the first display substrate and the second display substrate.

The display device may further include a filling material filled in the cell gap and including an organic material.

The color filters may include a first color filter, a second color filter, and a third color filter, and at least two color filters of the first color filter, the second color filter, and the third color filter may be overlapped with each other in the peripheral region.

The light emitting elements may include a first light emitting element, a second light emitting element, and a third light emitting element, each of the first light emitting element, the second light emitting element, and the third light emitting element may generate a blue source light, first and second filter openings may be defined in the third color filter to correspond to first and second pixel regions, respectively, a third color filter may be overlapped with the third pixel region, and the third color filter may be a blue color filter.

The light control patterns may include a first light control pattern, a second light control pattern, and a third light control pattern, and each of the first light control pattern and the second light control pattern may include a base resin and a quantum dot.

The third light control pattern may include a base resin and a scatterer.

The first display substrate may further include an upper cover layer which covers the split pattern and the light control patterns, and includes an inorganic material.

According to an embodiment, a method for manufacturing a display device includes: forming a working substrate including a first base layer including a display region and a non-display region, a circuit layer disposed on the first base layer and having a transistor, a display element layer including a light emitting element disposed on the circuit layer and connected to the transistor, and an encapsulation layer to cover the display element layer; forming a split pattern overlapped with the display region on the working substrate to include a first opening, a second opening, and a third opening; forming a first light control pattern in the first opening; forming a second light control pattern in the second opening; forming a third light control pattern in the third opening; and forming a dummy pattern on the first base layer overlapped with the non-display region. The third light control pattern and the dummy pattern include the same material.

The method may further include: forming a first display substrate by forming a lower cover layer to cover the split pattern, the first control pattern, the second control pattern, the third control pattern, and the dummy pattern; and laminating, with the first display substrate, a second display substrate including a second base layer, color filters disposed on a bottom surface of the second base layer, a lower refractive layer to cover the color filters, an upper cover layer to cover the lower refractive layer, and a step difference compensating layer that covers the upper cover layer and is overlapped with the non-display region.

The first display substrate and the second display substrate may be combined with each other through a sealing member in a vacuum-lamination process, while interposing a cell gap between the first display substrate and the second display substrate

The sealing member may be interposed between the step difference compensating layer and the dummy pattern.

### BRIEF DESCRIPTION OF THE FIGURES

The above and other objects and features of the present disclosure will become apparent by describing in detail embodiments thereof with reference to the accompanying drawings.

FIG. 1A is a perspective view illustrating a display device according to an embodiment of the present disclosure.

FIG. 1B is a plan view of a display device, according to an embodiment of the present disclosure.

FIG. 1C is a cross-sectional view taken along line I-I′ of FIG. 1B.

FIG. 2 is a plan view of a first display substrate according to an embodiment of the present disclosure.

FIG. 3 is an expanded plan view of a display region according to an embodiment of the present disclosure.

FIG. 4 is a cross-sectional view of a display device taken along line II-II′ of FIG. 3.

FIG. 5 is a cross-sectional view taken along line III-III′ of FIG. 1B.

FIG. 6 is a cross-sectional view of a display device according to an embodiment of the present disclosure.

FIG. 7 is a cross-sectional view of a display device according to an embodiment of the present disclosure.

FIG. 8 is a cross-sectional view of a display device according to an embodiment of the present disclosure.

FIG. 9 is a cross-sectional view of a display device according to an embodiment of the present disclosure.

FIGS. 10A to 101 are cross-sectional views illustrating a method for manufacturing a display device according to an embodiment of the present disclosure.

### DETAILED DESCRIPTION

In the specification, the expression that a first component (or area, layer, part, portion, etc.) is “on”, “connected with”, or “coupled to” a second component means that the first component is directly on, connected with, or coupled to the second component or means that a third component is disposed therebetween.

The same reference numeral refers to the same component. While thicknesses, proportions, and dimensions of components in drawings are examples of embodiments of the disclosure; these thicknesses, proportions, and dimensions may vary in alternate embodiments. The expression “and/or” may include one or more combinations of one or more of the associated listed items.

Although the terms “first”, “second”, etc. may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component. The singular forms are intended to include the plural forms unless the context clearly indicates otherwise.

In addition, the terms “under”, “below”, “on”, “above”, etc. are used to describe the correlation of components illustrated in drawings. The terms that are relative in concept are described based on a direction shown in drawings.

Hereinafter, embodiments of the present disclosure will be described with reference to accompanying drawings.

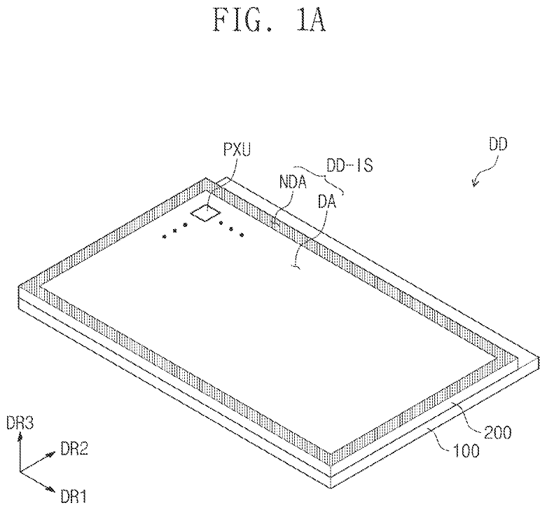

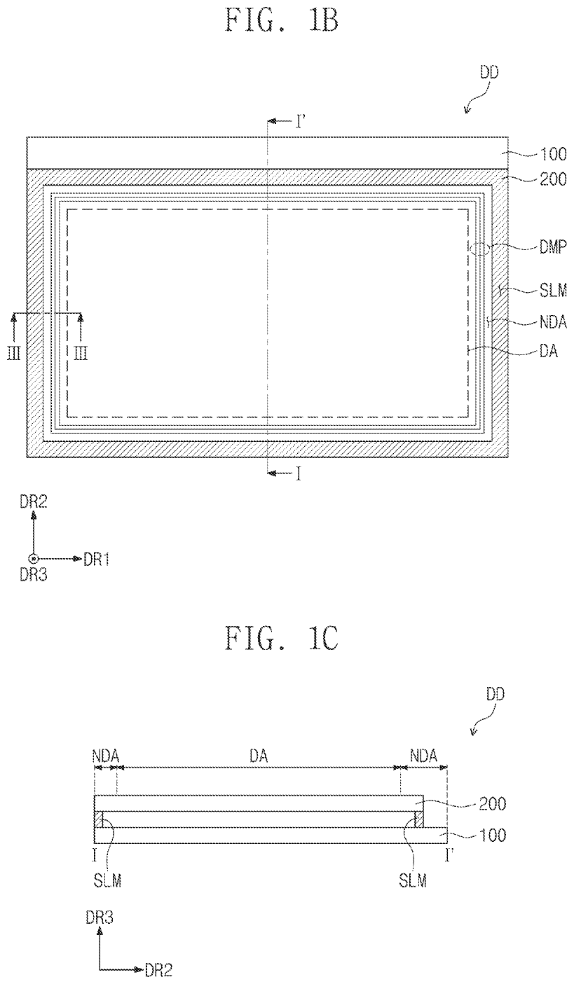

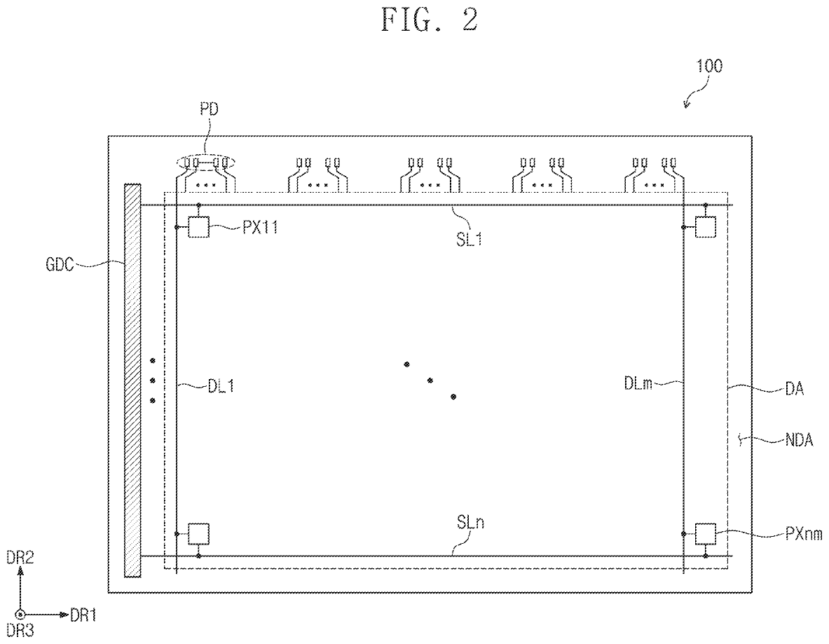

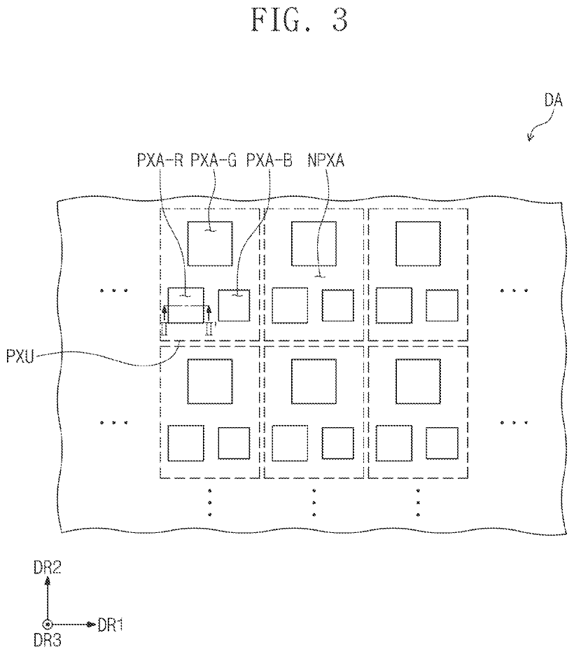

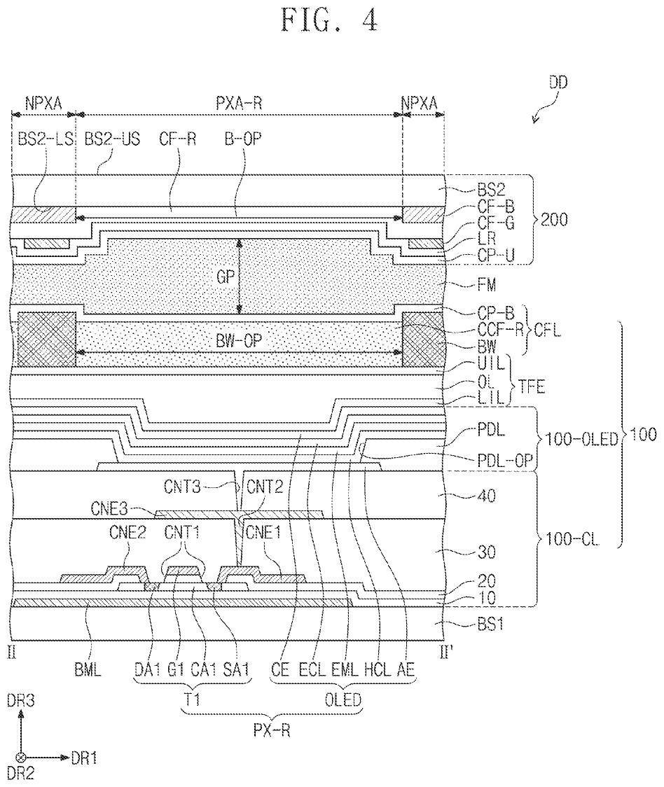

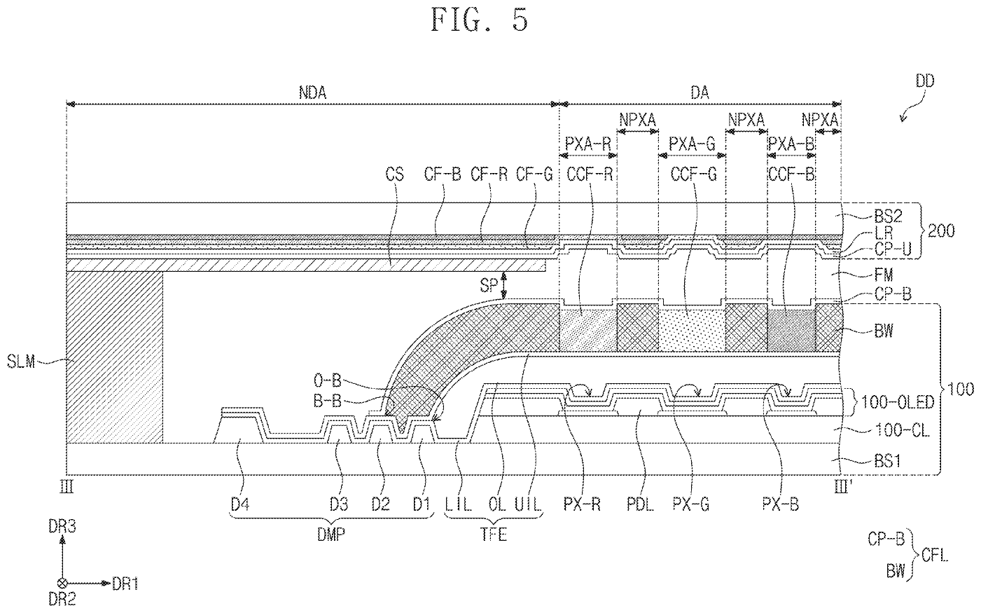

FIG. 1A is a perspective view illustrating a display device according to an embodiment of the present disclosure. FIG. 1B is a plan view of a display device, according to an embodiment of the present disclosure. FIG. 1C is a cross-sectional view taken along line I-I′ of FIG. 1B. FIG. 2 is a plan view of a first display substrate according to an embodiment of the present disclosure. FIG. 3 is an expanded plan view of a display region according to an embodiment of the present disclosure. FIG. 4 is a cross-sectional view of a display device taken along line II-II′ of FIG. 3. FIG. 5 is a cross-sectional view taken along line III-III′ of FIG. 1B.

Referring to FIG. 1A, a display device DD displays an image through a display surface DD-IS. The display surface DD-IS may be parallel to a surface that is defined by a first direction DR1 and a second direction DR2. A top surface of a member that is disposed on the uppermost side (or layer) of the display device DD may be defined as the display surface DD-IS.

A normal direction of the display surface DD-IS, that is, a thicknesses direction of the display device DD corresponds to a third direction DR3. A front surface (or a top surface) and a back surface (or a bottom surface) of each layer or unit of the display device DD are distinguished in the third direction DR3.

The display device DD includes a display region DA and a non-display region NDA. Unit pixels PXU are disposed in the display region DA, and are not disposed in the non-display region NDA. The non-display region NDA is defined along the edge of the display surface DD-IS. The non-display region NDA may surround the display region DA.

According to an embodiment of the present disclosure, the non-display region NDA is omitted or disposed only on one side of the display region DA. Although FIG. 1A illustrates the display device DD as a flat-surface type, the display device DD may have a curved shape, and may be rollable, or slidable from a housing.

The unit pixels PXU illustrated in FIG. 1A may be defined in the arrangement form of a row and a column. One unit pixel PXU may include at least one pixel as a minimum repeating unit. In addition, the one unit pixel PXU may include a plurality of pixels which provide light having different colors.

Referring to FIGS. 1B and 1C, the display device DD includes a first display substrate 100 (or a lower display substrate) and a second display substrate 200 (or an upper display substrate). The second display substrate 200 may be spaced apart from the first display substrate 100 while facing the first display substrate 100. A specific cell gap may be formed between the first display substrate 100 and the second display substrate 200. The cell gap may be maintained by a sealing member SLM which couples the first display substrate 100 to the second display substrate 200.

The sealing member SLM may include binder resin and inorganic fillers mixed with the binder resin. The sealing member SLM may further include other additives. The additive may include an amine-based curing agent and a photoinitiator. The additive may further include a silane-based additive and an acrylic additive. The sealing member SLM may include an inorganic material such as a frit.

The sealing member SLM overlaps the non-display region NDA, and the display region DA is disposed inside the sealing member SLM. Although the sealing member SLM aligned with the edge of the second display substrate 200 is illustrated when viewed in a plan view, the present disclosure is not limited thereto.

Although FIGS. 1B and 1C illustrate that the second display substrate 200 has an area or width smaller than an area of the first display substrate 100, the present disclosure is not limited thereto. A driving chip may be mounted or a circuit board may be bonded to a partial region of the first display substrate 100, which is exposed from the second display substrate 200. For example, the driving chip or circuit board may be disposed on a portion of the first display substrate 100 not covered by the second display substrate 200. According to an embodiment, a chip on film (COF) may be overlapped with the non-display region NDA, and may be bonded to the partial region of the first display substrate 100, which is exposed from the second display substrate 200.

Referring to FIG. 1B, a dam pattern DMP may be disposed inside the sealing member SLM. The dam pattern DMP may include a plurality of dam patterns. FIG. 1B illustrates three dam patterns by way of example. The dam pattern DMP may be overlapped with the non-display region NDA. At least one of the dam patterns may have a closed-line form. Although FIG. 1B illustrates each dam line has a closed-line form, the present disclosure is not limited thereto. The details of the dam patterns will be described later.

FIG. 2 is a plan view of the first display substrate 100 according to an embodiment of the present disclosure.

FIG. 2 illustrates the arrangement relationship among signal lines SL1 to SLn, and DL1 to DLm, and pixels PX11 to PXnm, when viewed in a plan view. The signal lines SL1 to SLn, and DL1 to DLm may include a plurality of gate lines SL1 to SLn and a plurality of data lines DL1 to DLm.

Each of the pixels PX11 to PXnm is connected to a relevant gate line of the plurality of gate lines SL1 to SLn and a relevant data line among the plurality of data lines DL1 to DLm. Each of the pixels PX11 to PXnm may include a pixel driving circuit and a light emitting element. Many more types of signal lines may be disposed on the first display substrate 100, depending on the configuration of the pixel driving circuit of the pixels PX11 to PXnm

A gate driving circuit GDC may be integrated into the first display substrate 100 through an oxide silicon gate driver circuit (OSG) process or an amorphous silicon gate driver circuit (ASG) process. The gate driving circuit GDC connected to the gate lines SL1 to SLn is disposed on one side (e.g., a first side) of the non-display region NDA. Pads PD connected to ends of the plurality of data lines DL1 to DLm are disposed on one side (e.g., a second side) of the non-display region. As illustrated in FIGS. 1B and 1C, the pads PD may be exposed from the second display substrate 200.

As illustrated in FIG. 3, the unit pixels PXU are arranged in the first direction DR1 and the second direction DR2. According to an embodiment, the unit pixel PXU may include a first pixel region PXA-R, a second pixel region PXA-G, and a third pixel region PXA-B that emit lights of different colors, respectively. The first pixel region PXA-R may emit a red light, the second pixel region PXA-G may emit a green light, and the third pixel region PXA-B may emit a blue light.

The first pixel region PXA-R, the second pixel region PXA-G, and the third pixel region PXA-B may be defined based on the second display substrate 200. A peripheral region NPXA is disposed between the first pixel region PXA-R, the second pixel region PXA-G, and the third pixel region PXA-B. The peripheral region NPXA sets the boundary among the first to third pixel regions PXA-R, PXA-G, and PXA-B to prevent color mixing among the first to third pixel regions PXA-R, PXA-G, and PXA-B. For example, the first pixel region PXA-R, the second pixel region PXA-G, and the third pixel region PXA-B may be spaced apart from one another.

Among the pixels PX11 to PXnm (see FIG. 2) of the first display substrate 100, a pixel overlapped with the first pixel region PXA-R of the second display substrate 200 may be defined as a first pixel, a pixel overlapped the second pixel region PXA-G of the second display substrate 200 may be defined as a second pixel, and a pixel overlapped with the third pixel region PXA-B of the second display substrate 200 may be defined as a third pixel. However, as described later, the first pixel, the second pixel, and the third pixel may have the same configuration. The first pixel, the second pixel, and the third pixel may merely be defined as pixels overlapped with the first pixel region PXA-R, the second pixel region PXA-G and the third pixel region PXA-B, respectively.

The first pixel, the second pixel, and the third pixel may include light emitting elements OLED (see FIG. 4), and the light emitting elements OLED (see FIG. 4) of the first pixel, the second pixel, and the third pixel may generate source lights having the same color. However, the light emitting elements of the first pixel, the second pixel, and the third pixel may have the same light emission area or mutually different light emission areas.

Source lights generated from the light emitting elements OLED (see FIG. 4) of the first, second, and third pixels are converted into lights having mutually different colors through the first pixel region PXA-R, the second pixel region PXA-G, and the third pixel region PXA-B. In the second display substrate 200 to be described later, the source lights generated from the first display substrate 100 is converted into light having another color.

Referring to FIG. 3, the first pixel region PXA-R and the third pixel region PXA-B are arranged in the same row, and the second pixel region PXA-G is arranged in a different row from the first pixel region PXA-R and the third pixel region PXA-B. The second pixel region PXA-G may have the largest area, and the third pixel region PXA-B may have the smallest area, but the present disclosure is not limited thereto. According to an embodiment, although the first pixel region PXA-R, the second pixel region PXA-G, and the third pixel region PXA-B having the shape of a square are provided, the arrangement form and the area of the pixel regions are not limited thereto.

The arrangement structures of the first pixel region PXA-R, the second pixel region PXA-G, and the third pixel region PXA-B of the unit pixels PXU illustrated in FIG. 3 are provided merely for illustrative purpose. Accordingly, the present disclosure is not limited thereto. According to an embodiment of the present disclosure, the first pixel region PXA-R, the second pixel region PXA-G, and the third pixel region PXA-B are arranged in the first direction DR1 and are arranged in the same row. Alternatively, the arrangement of the first pixel region PXA-R, the second pixel region PXA-G, and the third pixel region PXA-B in each of the unit pixels PXU does not need to be the same.

Hereinafter, the cross-sectional structures of the first display substrate 100 and the second display substrate 200 will be described in detail with reference to FIG. 3 while focusing on the first pixel region PXA-R. A specific cell gap GP may be formed between the first display substrate 100 and the second display substrate 200. The cell gap GP may be maintained to be in an empty space, or gas may be filled in the cell gap. Alternatively, the display device DD may further include a filling material FM filled in the cell gap GP. The filling material FM may include an epoxy-based organic material. FIG. 4 illustrates that the filling material FM is filled in the cell gap GP.

Referring to FIGS. 4 and 5, the first display substrate 100 may include a first base layer BS1 (or a lower base layer), a circuit layer 100-CL, a display device layer 100-OLED, an encapsulation layer TFE, and a light control layer CFL. The cross-sectional structure of the first display substrate 100 corresponding to the first pixel region PXA-R may be the same as the cross-sectional structure of the first display substrate 100, which corresponds to the second pixel region PXA-G and the third pixel region PXA-B illustrated in FIG. 3.

The first base layer BS1 may include a synthetic resin substrate or a glass substrate. In an embodiment, the first base layer BS1 include a first synthetic resin layer, a second synthetic resin layer, and an inorganic layer disposed between the first and second synthetic resin layers. The synthetic resin layer may include a thermosetting resin. In an embodiment, the synthetic resin layer is a polyimide-based resin layer, but is not limited thereto. The synthetic resin layer may include at least one of an acrylic-based resin, a methacryl-based resin, a polyisoprene-based resin, a vinyl-based resin, an epoxy-based resin, a urethane-based resin, a cellulose-based resin, a siloxane-based resin, a polyamide-based resin, and a perylene-based resin.

A light blocking pattern BML may be disposed on the first base layer BS1. The light blocking pattern BML may include metal. A signal line may be disposed on the same layer as the light blocking pattern BML. A first insulating layer 10 covering the light blocking pattern BML is disposed on the first base layer BS1.

A semiconductor pattern overlapped with the light blocking pattern BML is disposed on the first insulating layer 10. The semiconductor pattern may have different doping concentrations depending on regions, and the doping concentration may determine an electrical characteristic. In an embodiment, the semiconductor pattern includes a first region having a higher conductivity and a second region having a lower conductivity. The first region may be doped with N-type dopants or P-type dopants. A P-type transistor may include a doping region doped with the P-type dopants, and an N-type transistor may include a doping region doped with the N-type dopants. The second region may be a non-doping region or a doping region having a concentration lower than a concentration of the first region.

The semiconductor pattern may include a source region SA1, a channel region CAl (or an active region), and a drain region DAL. A second insulating layer 20 is disposed on the first insulating layer 10. Contact holes CNT1 are defined in the second insulating layer 20 to expose the source region SA1 and the drain region DA1. In an embodiment, the first insulating layer 10 and the second insulating layer 20 are an inorganic layer.

A gate electrode G1 is disposed on the second insulating layer 20. Connection electrodes CNE1 and CNE2 are disposed on the second insulating layer 20. The first connection electrode CNE1 may electrically connect the source region SA1 of a first transistor T1 to a drain or source of another transistor included in the pixel circuit. The second connection electrode CNE2 may electrically connect the drain region DA1 of the first transistor T1 to another transistor or signal line included in the pixel circuit.

A third insulating layer 30 is disposed on the second insulating layer 20. A third connection electrode CNE3 is disposed on the third insulating layer 30. The third connection electrode CNE3 may be connected to the first connection electrode CNE1 through a contact hole CNT2 formed through the third insulating layer 30. A fourth insulating layer 40 is disposed on the third insulating layer 30. A first electrode AE is disposed on a fourth insulating layer 40. According to an embodiment, the first electrode AE will be described as the anode AE. The anode AE may be connected to the third connection electrode CNE3 through a contact hole CNT3 formed through the fourth insulating layer 40. The third insulating layer 30 and the fourth insulating layer 40 may be an organic layer.

The light emitting element OLED and a pixel defining layer PDL are disposed on the fourth insulating layer 40. An opening PDL-OP in the pixel defining layer PDL exposes at least a portion of the anode AE. The opening PDL-OP of the pixel defining layer PDL may define a light emitting region. The region in which the pixel defining layer PDL is disposed may be defined as a non-light emitting region.

A hole control layer HCL may be disposed in common in the light emitting region and the non-light emitting region. A common layer such as the hole control layer HCL may be commonly overlapped with the plurality of unit pixels PXU illustrated in FIG. 3. In this specification, the layers formed as a common layer may be entirely disposed in the display region DA (see FIG. 1C) and the non-display region NDA (see FIG. 1C). The hole control layer HCL may include a hole transport layer and a hole injection layer.

A light emitting layer EML is disposed on the hole control layer HCL. The light emitting layer EML may be commonly disposed in the light emitting region and the non-light emitting region. The light emitting layer EML may generate source light. The light emitting layer EML may include an organic light emitting material or an inorganic light emitting material. According to an embodiment, the source light may be a blue light.

An electron control layer ECL is disposed on the light emitting layer EML. The electron control layer ECL may include an electron transport layer and an electron injection layer. A second electrode CE is disposed on the electron control layer ECL. According to an embodiment, the second electrode CE will be referred to as the cathode CE. The hole control layer HCL, the light emitting layer EML, and the electron control layer ECL may be defined as common layers.

The encapsulation layer TFE is disposed on the cathode CE. The encapsulation layer TFE is commonly disposed in the plurality of unit pixel PXU as illustrated in FIG. 3. According to an embodiment, the encapsulation layer TFE directly covers the cathode CE. The encapsulation layer TFE may include a first inorganic layer LIL, an organic layer OL, and a second inorganic layer UIL. However, the present disclosure is not limited thereto. The encapsulation layer TFE may further include a plurality of inorganic layers and a plurality of organic layers.

The first inorganic layer LIL may make contact with the second electrode CE. The first inorganic layer LIL may prevent external moisture or oxygen from being infiltrated into the light emitting layer EML. For example, the first inorganic layer LIL may include a silicon nitride, a silicon oxide, or the compound thereof. The first inorganic layer LIL may be formed through a deposition process.

The organic layer OL may be disposed on the first inorganic layer LIL to make contact with the first inorganic layer LIL. The organic layer OL may provide a flat surface on the first inorganic layer LIL. In an embodiment, any roughness formed on a top surface of the first inorganic layer LIL or particles present on the first inorganic layer LIL are covered by the organic layer OL, thereby preventing a surface state of the top surface of the first inorganic layer LIL from exerting an influence on components formed on the organic layer OL. The organic layer OL may include an organic material and may be formed through a solution process such as a spin coating process, a slit coating process, or an inkjet process.

During the process of forming the organic layer OL, the solution including the organic material may be coated only up to a first dam pattern D1 of the dam pattern DMP. Accordingly, a boundary O-B of the organic layer OL may be determined by the first dam pattern D1 when viewed in a plan view.

The second inorganic layer UIL is disposed on the organic layer OL to cover the organic layer OL. The second inorganic layer UIL may be stably formed on a relatively flat surface, as compared with when the second inorganic layer UIL is disposed on the first inorganic layer LIL. The second inorganic layer UIL seals moisture discharged from the organic layer OL to prevent the moisture from flowing out. For example, the second inorganic layer UIL may include a silicon nitride, a silicon oxide, or the compound thereof. The second inorganic layer UIL may be formed through a deposition process.

The light control layer CFL is disposed on the encapsulation layer TFE. In an embodiment, the light control layer CFL includes a split pattern BW, a lower cover layer CP-B and light control patterns CCF-R, CCF-G, and CCF-B. According to one embodiment, the split pattern BW may be provided as one body pattern.

The split pattern BW may include openings BW-OP corresponding to the first, second, and third pixel regions PXA-R, PXA-G, and PXA-B. FIG. 4 illustrates one opening BW-OP overlapped with the first pixel region PXA-R by way of example.

According to an embodiment, the split pattern BW, which serves a pattern having a black color, may be a black matrix. Accordingly, the split pattern BW may include a black coloring agent. The black coloring agent may include a black dye and a black pigment. The black coloring agent may include metal, such as carbon black, and chromium, or an oxide thereof.

In an embodiment, during the process of forming the split pattern BW, the solution including the organic material is coated only up to a second dam pattern D2 of the dam pattern DMP. Accordingly, when viewed in a plan view, a boundary B-B of the split pattern BW may be determined by the second dam pattern D2. According to an embodiment, the second dam pattern D2 defining the boundary B-B of the split pattern BW is more adjacent or closer to the sealing member SLM than the first dam pattern D1 defining the boundary O-B of the organic layer OL. Accordingly, the end of the organic layer OL defining the boundary O-B of the organic layer OL may be covered by the split pattern BW. However, the boundary O-B of the organic layer OL and the boundary B-B of the split pattern BW are not limited thereto. For example, as long as the split pattern BW is disposed more adjacent to the sealing member SLM rather than the organic layer OL, dam patterns defining the boundary are not limited to any one dam pattern.

In embodiment, the first, second, and third light control patterns CCF-R, CCF-G, and CCF-B are disposed in the openings BW-OP, respectively. The first, second, and third light control patterns CCF-R, CCF-G, and CCF-B change the optical properties of the source light.

The first and second light control patterns CCF-R and CCF-G may absorb source light and then generate lights having different colors. The third light control pattern CCF-B may transmit and scatter some of the incident source light. As described above, the third light control pattern CCF-B has an optical function different from optical functions of the first and second light control patterns CCF-R and CCF-G.

Each of the first and second light control patterns CCF-R and CCF-G may include a base resin and quantum dots mixed (or dispersed) in the base resin. According to an embodiment, the first and second light control patterns CCF-R and CCF-G may be defined as quantum dot patterns and include mutually different quantum dots. The base resin is a medium in which quantum dots are dispersed and may be formed of various resin compositions that may be generally referred to as a binder. However, the present disclosure is not limited thereto, and any medium capable of dispersing quantum dots in the present specification may be referred to as a base resin regardless of a name of a medium, another additional function of the medium, a material included in the medium. The base resin may be a polymer resin. For example, the base resin may be an acrylic resin, a urethane resin, a silicone resin, or an epoxy resin. The base resin may be a transparent resin.

The quantum dot may be a particle that converts the wavelength of incident light. Quantum dots are materials having a crystal structure of several nanometers, including hundreds to thousands of atoms, and have a quantum confinement effect that increases the energy band gap due to the small size of the quantum dots. When a light with a wavelength higher in energy than the band gap is incident to the quantum dot, the quantum dot absorbs the light, becomes excited, and falls to the bottom while emitting a light having a specific wavelength. The light of the emitted wavelength has a value corresponding to the band gap. When the size and the composition of the quantum dot are adjusted, the light emitting characteristics from the quantum confinement effect can be adjusted. The diameter of the quantum dot according to an embodiment may be, for example, about 1 nanometer (nm) to 10 nm.

Quantum dots may be synthesized by a wet chemical process, a metal organic chemical deposition (MOCVD) process, a molecular beam epitaxy (MBE) process, or a similar process. The wet chemical process is a manner of growing quantum dot particle crystals after mixing an organic solvent and a precursor material. When the crystal is grown, the organic solvent naturally serves as a dispersant coordinated on the surface of the quantum dot crystal, and the growth of the crystal may be controlled. Accordingly, the wet chemical process is more easily performed than a vapor deposition scheme, such as a metal organic chemical vapor deposition (MOCVD) or molecular beam epitaxy (MBE), and may control the growth of quantum dot particles through a low-cost process.

Quantum dots may include a group III-VI compound, a group II-VI compound, a group III-V compound, a group I-III-VI compound, a group IV-VI compound, a group IV element or compound, or any combination thereof.

For example, the group III-VI compound may include binary compounds, such as GaS, Ga₂S₃, GaSe, GaTe, InS, InSe, In₂Se₃, and InTe, three-element compounds, such as InGaS₃, and InGaSe₃, or any combination thereof.

The group II-VI compound may include a binary compound, such as CdS, CdSe, CdTe, ZnS, ZnSe, ZnTe, ZnO, HgS, HgSe, HgTe, MgSe, or MgS, a three-element compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, a four-element compound, such as CdZnSeS, CdZnSeTe, CdZnSTe, CdHgSeS, CdHgSeTe, CdHgSTe, HgZnSeS, HgZnSeTe, or HgZnSTe, and any combination thereof, by way of example. Meanwhile, the group II-VI compound may further include a group I metal and/or a group IV element. The group I-II-VI compound may be selected from CuSnS or CuZnS, and the group II-IV-VI compound may include ZnSnS. The group I-II-IV-VI compound may be selected from the group consisting of Cu₂ZnSnS₂, Cu₂ZnSnS₄, Cu₂ZnSnSe₄, Ag₂ZnSnS₂, and the mixture thereof.

The group III-V compound may include a binary compound such as GaN, GaP, GaAs, GaSb, AlN, AlP, AlAs, AlSb, InN, InP, InAs, or InSb, a three-element compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and a four-element compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, or the combination thereof, by way of example. Meanwhile, the group III-V compound may further include a group II element. The group III-V compound including the group II element may include InZnP, InGaZnP, or InAlZnP, by way of example.

The group I-III-VI compound may include a three-element compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂, a four-element compound, such as AgInGaS₂, or AgInGaSe₂, or the combination thereof, by way of example.

The group IV-VI compound may include a binary compound, such as SnS, SnSe, SnTe, PbS, PbSe, or PbTe, a three-element compound, such as SnSeS, SnSeTe, SnSTe, PbSeS, PbSeTe, PbSTe, SnPbS, SnPbSe, or SnPbTe, a four-element compound, such as SnPbSSe, SnPbSeTe, or SnPbSTe, or any combination thereof, by way of example.

The group II-IV-V compound may include a three-element compound selected from the group consisting of ZnSnP, ZnSnP2, ZnSnAs2, ZnGeP₂, ZnGeAs₂, CdSnP₂, CdGeP₂, and the mixture thereof.

The group IV element or compound may include a single-element compound, such as Si or Ge, a binary compound, such as SiC or SiGe, or any combination thereof.

Each element included in the multi-element compound such as the binary compound, the three-element compound, and the four-element compound may be present in the particle at a uniform concentration or a non-uniform concentration. In other words, the formula refers to the type of element included in the compound, and the element ratio in the compound may be varied. For example, AgInGaS₂ may refer to AglnₓGap₁₋ₓS₂ (x is a real number between 0 and 1).

Meanwhile, the quantum dot may have a single structure or a core-shell double structure in which the concentration of each element included in the corresponding quantum dot is uniform. For example, the material included in the core and the material contained in the shell may be different from each other.

The shell of each of the quantum dots may function as a protective layer to maintain a semiconductor characteristic by preventing the chemical property of the core from being changed, and/or a charging layer to apply an electrophoretic property to the quantum dot. The shell may be a single layer or a multilayer. The interface between the core and the shell may have a concentration gradient in which the concentration of the element present in the shell decreases toward the center. The core/shell structure may have a concentration gradient in which the concentration of elements present in the shell is lowered toward the core.

The shell of the quantum dot includes a metal or non-metal oxide, compound, or the combinations thereof, by way of example. The metal or non-metal oxide may include a binary compound, such as SiO₂, Al₂O₃, TiO₂, ZnO, MnO, Mn₂O₃, Mn₃O₄, CuO, FeO, Fe₂O₃, Fe₃O₄, CoO, CO₃O₄, or NiO, a three-element compound, such as MgAl₂O₄, CoFe₂O₄, NiFe₂O₄, or CoMn₂O₄, any combination thereof. The compound may include a group III-VI compound, a group II-VI compound, a group III-V compound, a group I-III-VI compound, a group IV-VI compound, or any combination thereof. The compound may include CdS, CdSe, CdTe, ZnS, ZnSe, ZnTe, ZnSeS, ZnTeS, GaAs, GaP, GaS, GaSe, AgGaS, AgGaS2, GaSb, HgS, HgSe, HgTe, InAs, InP, InGaP, InSb, AlAs, AlP, AlSb, or any combination thereof.

Each element included in a multi-element compound such as a binary compound and a three-element compound may be present in the particles at a uniform concentration or a non-uniform concentration. In other words, the chemical formula refers to the type of an element included in the compound, and the element ratio in the compound may be varied.

The quantum dots may have a full width of half maximum (FWHM) of a light emitting wavelength spectrum of about 45 nm or less, specifically about 40 nm or less, and more specifically about 30 nm or less. In the range, color purity or color reproducibility may be increased. In addition, since a light emitted through these quantum dots is emitted in all directions, a viewing angle may be increased.

In addition, quantum dots may specifically have the forms of spherical, pyramid, multi-arm, or cubic nano-particles, nano tubes, nanowires, nanofibers, and nano-plate particles.

As the size of the quantum dot is adjusted and the element ratio in the quantum dot compound is adjusted, the energy band gap is adjusted, and thus, a light having various wavelength bands may be obtained in a quantum dot light emitting layer. As the above-described quantum dot (quantum dots having mutually different sizes are used or different element ratios are provided in the quantum dot compound) is used, light emitting elements emitting lights having several wavelengths may be implemented. Specifically, as the size of the quantum dot or the element ratio in the quantum dot compound is adjusted, a red light, a green light, and/or a blue light is selectively emitted. In addition, the quantum dots may be configured to emit a white light by combining lights having various colors.

According to an embodiment, the first light control pattern CCF-R may be a red quantum dot pattern that absorbs a source light and then generates a red light. The second light control pattern CCF-G may be a green quantum dot pattern that generates a green light after absorbing the source light. The first light control pattern CCF-R and the second light control pattern CCF-G may further include scatterers.

The third light control pattern CCF-B may include a base resin and scatterers mixed (or dispersed) in the base resin. The third light control pattern CCF-B may be a scattering pattern for scattering a source light. The scatterer may be a particle having a larger density or specific gravity. The scattered particles may include titanium oxide (TiO₂) or silica-based nanoparticles.

According to an embodiment, the light control layer CFL may further include a lower cover layer CP-B. The lower cover layer CP-B may have a single layer/multi-layer structure. The lower cover layer CP-B may include a silicon oxide, a silicon nitride, or a silicon oxynitride. In an embodiment, the lower cover layer CP-B seals the split pattern BW, the first, second, and third light control patterns CCF-R, CCF-G, and CCF-B to prevent damage to the split pattern BW, and the first, second, and third light control patterns CCF-R, CCF-G, and CCF-B in a subsequent process.

The second display substrate 200 may be spaced apart from the first display substrate 100 (or the lower display substrate) while interposing the sealing member SLM and the cell gap GP between the second display substrate 200 and the first display substrate 100. According to an embodiment of the present disclosure, when the second display substrate 200 (or the upper display substrate) includes the light control layer CFL, the first display substrate 100 and the second display substrate 200 may have a dent failure due to the thickness of the split pattern BW including the organic material and the thickness of the organic layer OL, which includes the organic material, of the encapsulation layer TFE in the vacuum lamination process for the first display substrate 100 and the second display substrate 200 through the sealing member SLM.

According to an embodiment of the present disclosure, since the split pattern BW including the organic material is provided to the first display substrate 100 disposed at a lower portion, the thickness of the sealing member SLM may be adjusted, thereby maintaining a space SP between the first display substrate 100 and the second display substrate 200. Accordingly, the dent failure may be prevented in the split pattern BW and the organic layer OL in the vacuum lamination process for the first display substrate 100 and the second display substrate 200.

In an embodiment, since the split pattern BW including the organic material covers the organic layer OL in the non-display region NDA, outside moisture is blocked from being introduced into a display element layer 100-OLED. Accordingly, the display device DD having increased reliability may be provided.

The second display substrate 200 may include a second base layer BS2 (or an upper base layer). The second base layer BS2 may include a synthetic resin substrate or a glass substrate. The second base layer BS2 may include a thermosetting resin. In an embodiment, the synthetic resin layer is a polyimide-based resin layer, but is not limited thereto. The synthetic resin layer may include at least one of an acrylic-based resin, a methacryl-based resin, a polyisoprene-based resin, a vinyl-based resin, an epoxy-based resin, a urethane-based resin, a cellulose-based resin, a siloxane-based resin, a polyamide-based resin, and a perylene-based resin.

A portion of a bottom surface BS2-LS of the second base layer BS2 may overlap the color filters CF-R, CF-G and CF-B. Referring to FIGS. 4 and 5, the color filters CF-R, CF-G, and CF-B may include the first, second, and third color filters CF-R, CF-G, and CF-B overlapped with the first, second, and third pixel regions PXA-R, PXA-G, and PXA-B. The first color filter CF-R, the second color filter CF-G, and the third color filter CF-B may be a red color filter, a green color filter, and a blue color filter, respectively.

The first pixel region PXA-R, the second pixel region PXA-G, the third pixel region PXA-B, and the peripheral region NPXA may be defined by the first, second, and third color filters CF-R, CF-G, and CF-B. The peripheral region NPXA may be defined as an overlap region between at least two color filters of the first, second, and third color filters CF-R, CF-G, and CF-B. The first pixel region PXA-R may be defined as a region overlapped with only the first color filter CF-R, the second pixel region PXA-G may be defined as a region overlapped with only the second color filter CF-G, and the third pixel region PXA-B may be defined as a region overlapped with only the third color filter CF-B.

When at least two color filters are overlapped with each other, an effect of blocking an external light is increased to produce a black matrix function. In addition, the overlap structure of the at least two color filters may prevent colors from being mixed. In this regard, the overlap structure of the color filters may correspond to a light blocking structure.

A filter opening B-OP corresponding to the first pixel region PXA-R may be defined in the second color filter CF-G and the third color filter CF-B. To correspond to the filter opening B-OP, a filter opening corresponding to the second pixel region PXA-G may be defined in the first color filter CF-R and the third color filter CF-B, and a filter opening corresponding to the third pixel region PXA-B may be defined in the first color filter CF-R and the second color filter CF-G.

The second display substrate 200 may include a lower refractive layer LR covering the first, second, and third color filters CF-R, CF-G, and CF-B. The lower refractive layer LR may cover the first, second, and third color filters CF-R, CF-G, and CF-B. The lower refractive layer LR may have a single layer/multi-layer structure. The lower refractive layer LR may increase light efficiency of the light control layer CFL. According to an embodiment, the lower refractive layer LR is omitted from the second display substrate 200. In this case, an upper cover layer CP-U may directly make contact with the first, second, and third color filters CF-R, CF-G, and CF-B.

The second display substrate 200 may further include the upper cover layer CP-U disposed on a bottom surface of the lower refractive layer LR. The upper cover layer CP-U may cover the first, second, and third color filters CF-R, CF-G, and CF-B to prevent the first, second, and third color filters CF-R, CF-G, and CF-B from being damaged in the subsequent process. According to an embodiment, the upper cover layer CP-U is omitted from the second display substrate 200. In this case, the lower refractive layer LR may directly contact the first, second, and third color filters CF-R, CF-G, and CF-B.

The second display substrate 200 may further include a step difference compensating layer CS. The step difference compensating layer CS is disposed on a bottom surface of the upper cover layer CP-U overlapped with the non-display region NDA. The step difference compensating layer CS may compensate for the step difference made in the second display substrate 200 in the process of forming the first, second, and third color filters CF-R, CF-G, and CF-B and the upper cover layer CP-U. Accordingly, the sealing member SLM may be provided on a flat surface having the step difference compensating layer CS and a vacuum lamination process may be performed with respect to the sealing member SLM and the first display substrate 100.

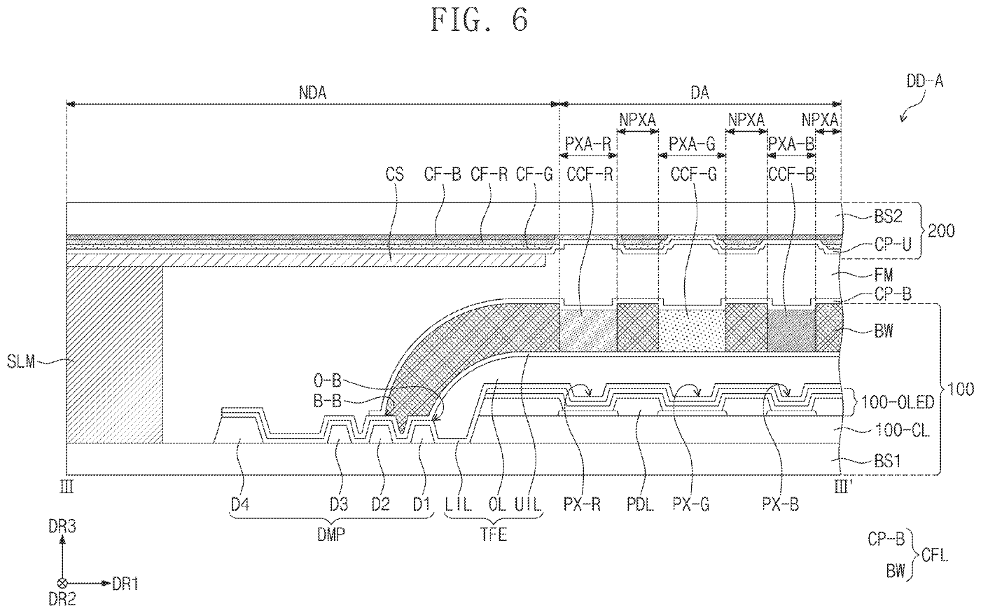

FIG. 6 is a cross-sectional view of a display device according to an embodiment of the present disclosure. The same/similar reference numerals will be assigned to the same/similar components to components described with reference to FIGS. 4 and 5 and thus description of the same/similar components will be omitted.

According to an embodiment, a display device DD-A may include the first display substrate 100 and the second display substrate 200. The display device of FIG. 3 may be implemented by the display device DD-A. The first display substrate 100 and the second display substrate 200 may be spaced apart from each other while interposing the sealing member SLM between the first display substrate 100 and the second display substrate 200. A filling material FM may be interposed in the space between the first display substrate 100 and the second display substrate 200.

The first display substrate 100 may include the first base layer BS1, the circuit layer 100-CL, the display device layer 100-OLED, the encapsulation layer TFE, and the light control layer CFL. The first display substrate 100 may include the dam pattern DMP. The dam pattern DMP may include dam patterns D1, D2, D3, and D4 to surround at least a portion of the display region DA. Each of the dam patterns D1, D2, D3, and D4 may include the same material as a material of at least one of insulating materials included in the display element layer 100-OLED. Each of the dam patterns D1, D1, D2, and D3 may have a single-layer/multi-layer structure.

The second display substrate 200 may include a second base layer BS2, the color filters CF-R, CF-G, and CF-B, the upper cover layer CP-U, and the step difference compensating layer CS.

According to an embodiment, the display device DD-A has no lower refractive layer LR (see FIG. 5) which is different from the display device DD illustrated in FIG. 5. Accordingly, the color filters CF-R, CF-G, and CF-B may be sealed by the upper cover layer CP-U, and the upper cover layer CP-U may prevent the color filters CF-R, CF-G, and CF-B from being damaged in the subsequent process.

In addition, the lower refractive layer LR (See FIG. 5) is removed from the second display substrate 200, to prevent moisture from being introduced into the first display substrate 100 and the second display substrate 200 through the lower refractive layer LR (see FIG. 5) in a hot and humid environment. Accordingly, the display device DD-A increased in lifespan of the light emitting element OLED (see FIG. 4) may be provided.

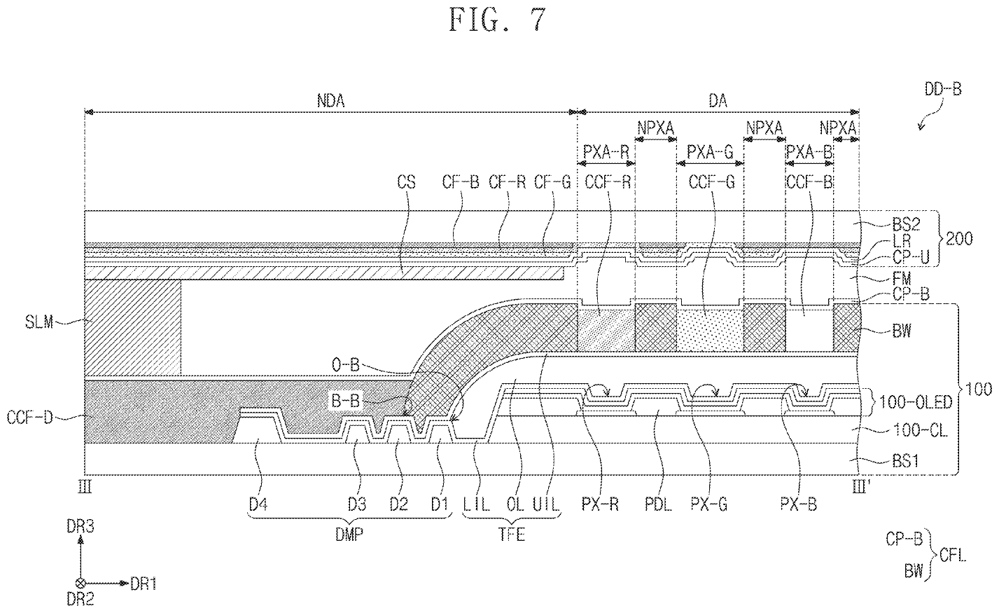

FIG. 7 is a cross-sectional view of a display device according to an embodiment of the present disclosure. The same/similar reference numerals will be assigned to the same/similar components to components described with reference to FIGS. 4 and 5 and thus duplication description will be omitted.

According to an embodiment, a display device DD-B may include the first display substrate 100 and the second display substrate 200. The display device of FIG. 3 may be implemented by the display device DD-B. The first display substrate 100 and the second display substrate 200 may be spaced apart from each other while interposing the sealing member SLM between the first display substrate 100 and the second display substrate 200. A filling material FM may be interposed in the space between the first display substrate 100 and the second display substrate 200.

The first display substrate 100 may include the first base layer BS1, the circuit layer 100-CL, the display device layer 100-OLED, the encapsulation layer TFE, and the light control layer CFL. The light control layer CFL may include the split pattern BW, the lower cover layer CP-B, and light control patterns CCF-R, CCF-G, and CCF-B.

The second display substrate 200 may include the second base layer BS2, the color filters CF-R, CF-G, and CF-B, the lower refractive layer LR, the upper cover layer CP-U, and the step difference compensating layer CS.

According to an embodiment, the first display substrate 100 further includes a dummy pattern CCF-D. The dummy pattern CCF-D may be disposed on the first base layer BS1 overlapped with the non-display region NDA.

In an embodiment, the dummy pattern CCF-D includes the same material as the third light control pattern CCF-B among the light control patterns CCF-R, CCF-G, and CCF-B. The dummy pattern CCF-D may be formed in the same process as an inkjet process of forming the third light control pattern CCF-B. When the dummy pattern CCF-D is formed through the ink-jet process, the thickness of the dummy pattern CCF-D in the third direction DR3 may be more easily adjusted.

The sealing member SLM may be disposed on the dummy pattern CCF-D. According to an embodiment, an adhesive layer for coupling the dummy pattern CCF-D and the sealing member SLM may be further included.

According to an embodiment, the dummy pattern CCF-D is disposed under the sealing member SLM to reduce a dent failure caused in the vacuum lamination process for the first display substrate 100 and the second display substrate 200. When the distance between the first display substrate 100 and the second display substrate 200 is uniformly maintained by using the dummy pattern CCF-D in the vacuum lamination process of the first display substrate 100 and the second display substrate 200, the resilient force of the first base layer BS1 and/or the second base layer BS2 made due to the step difference between the first display substrate 100 and the second display substrate 200 may be reduced/canceled.

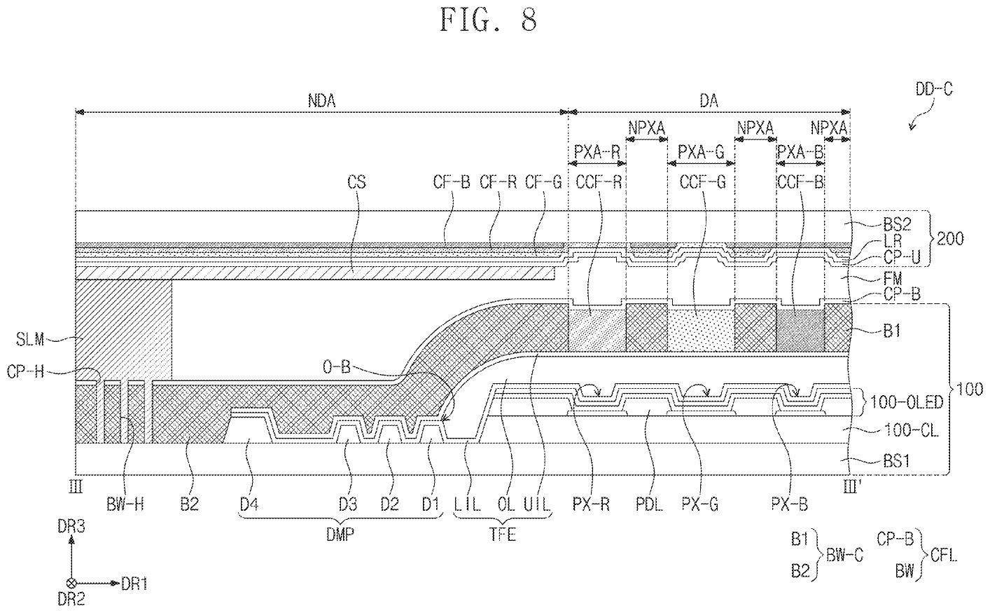

FIG. 8 is a cross-sectional view of a display device according to an embodiment of the present disclosure. The same/similar reference numerals will be assigned to the same/similar components to components described with reference to FIGS. 4 and 5 and thus redundant description will be omitted.

According to an embodiment, a display device DD-C may include the first display substrate 100 and the second display substrate 200. The display device of FIG. 3 may be implemented by the display device DD-C. The first display substrate 100 and the second display substrate 200 may be spaced apart from each other while interposing the sealing member SLM between the first display substrate 100 and the second display substrate 200. A filling material FM may be disposed in the space between the first display substrate 100 and the second display substrate 200.

The first display substrate 100 may include the first base layer BS1, the circuit layer 100-CL, the display device layer 100-OLED, the encapsulation layer TFE, and the light control layer CFL. According to an embodiment, the light control layer CFL may include the split pattern BW, the lower cover layer CP-B, and the light control patterns CCF-R, CCF-G, and CCF-B.

The second display substrate 200 may include the second base layer BS2, color filters CF-R, CF-G, and CF-B, the lower refractive layer LR, the upper cover layer CP-U, and the step difference compensating layer CS.

According to an embodiment, a split pattern BW-C is present that includes a first part B1 and a second part B2. The first part B1 may overlap with the display region DA, and the second part B2 may overlap with the non-display region NDA. The second part B2 may overlap with the sealing member SLM in the non-display region NDA. Although the first part B1 and the second part B2 are separated from each other for convenience of explanation, the first part B1 and the second part B2 may actually be part of a single pattern. Accordingly, the first part B1 and the second part B2 may include the same material and may be formed through the same process.

The second part B2 may include at least one pattern hole BW-H which is formed through the split pattern BW-C while extending from a top surface to a bottom surface of the split pattern BW-C. Although FIG. 8 illustrates three pattern holes BW-H, the number of pattern holes BW-H is not limited thereto. The sealing member SLM may extend through the pattern holes BW-H.

Each of the pattern holes BW-H may be overlapped with the sealing member SLM. The sealing member SLM may be hardened in the vacuum lamination process for the first display substrate 100 and the second display substrate 200 and placed inside the pattern holes BW-H. Accordingly, the coupling force between the split pattern BW-C and the sealing member SLM may be increased in the non-display region NDA. In addition, as parts, which are provided in the pattern holes BW-H, of the sealing member SLM make contact with the circuit layer 100-CL, the coupling force between the sealing member SLM and the first display substrate 100 may be increased.

In addition, when the split pattern BW-C is formed through an ink-jet process, the thickness of the second part B2 in the third direction DR3 may be more easily adjusted.

According to an embodiment, the second part B2 that can be adjusted in thickness is disposed under the sealing member SLM to reduce a dent failure caused in the vacuum lamination process for the first display substrate 100 and the second display substrate 200. When the distance between the first display substrate 100 and the second display substrate 200 is uniformly maintained by using the second part B2 in the vacuum lamination process of the first display substrate 100 and the second display substrate 200, the resilient force of the first base layer BS1 and/or the second base layer BS2 made due to the step difference between the first display substrate 100 and the second display substrate 200 may be reduced/canceled.

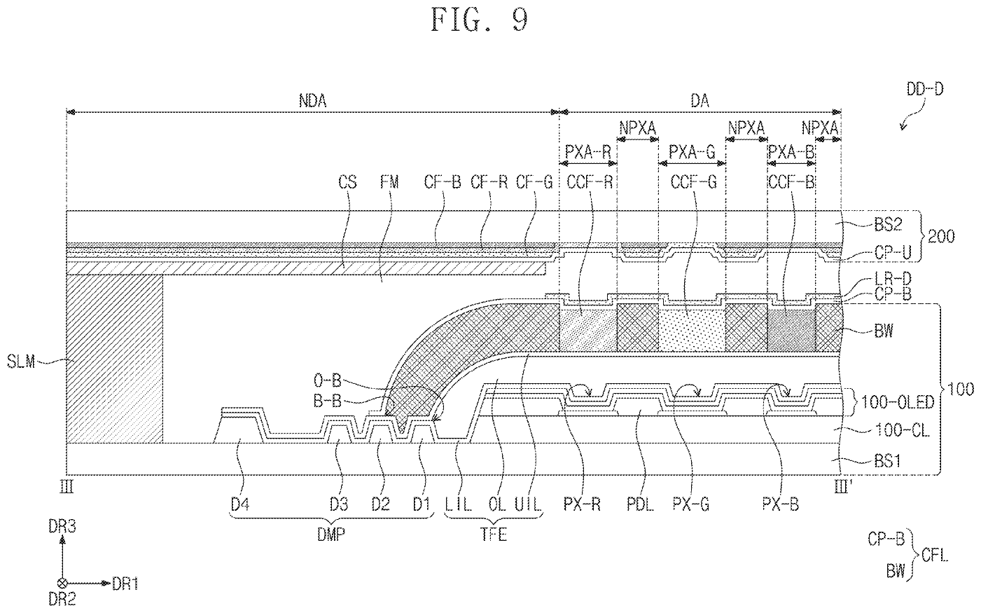

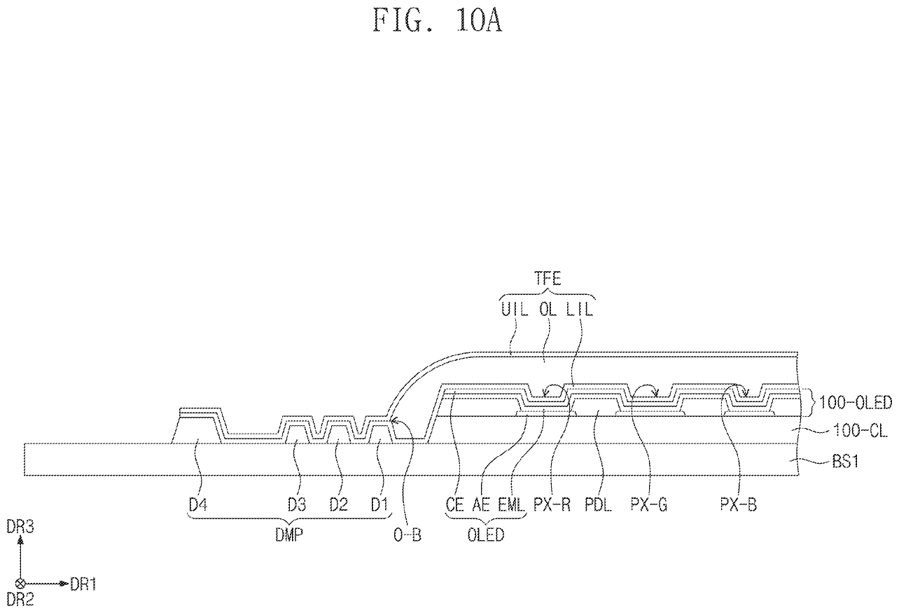

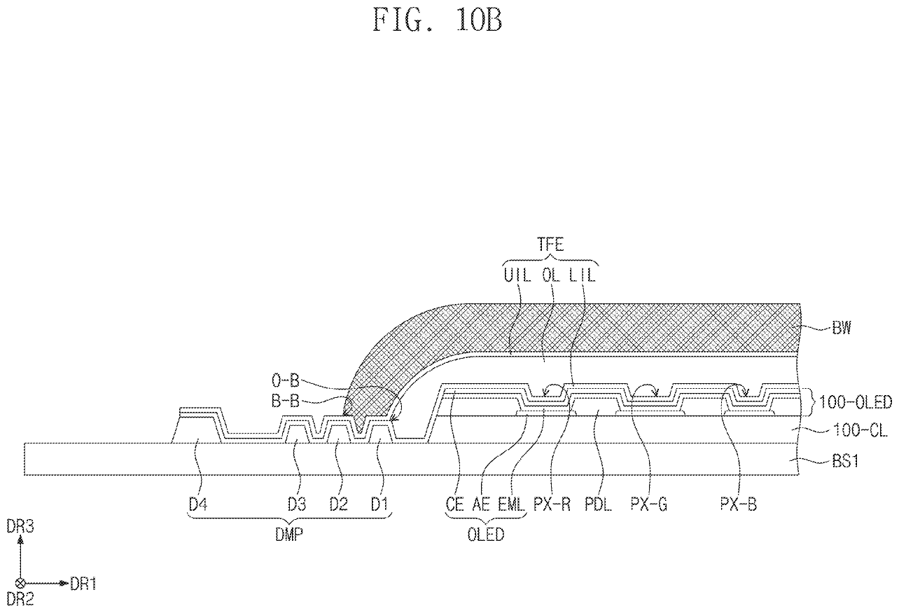

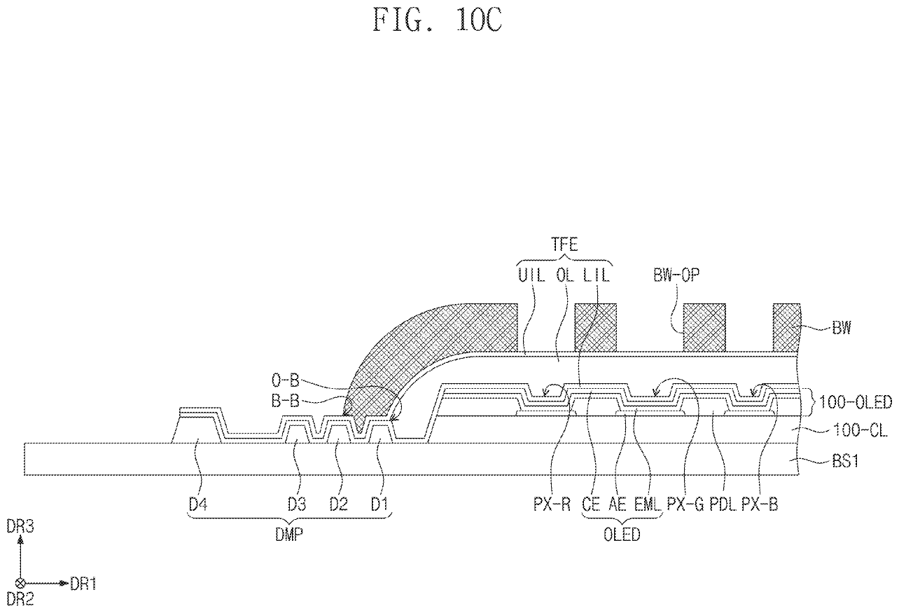

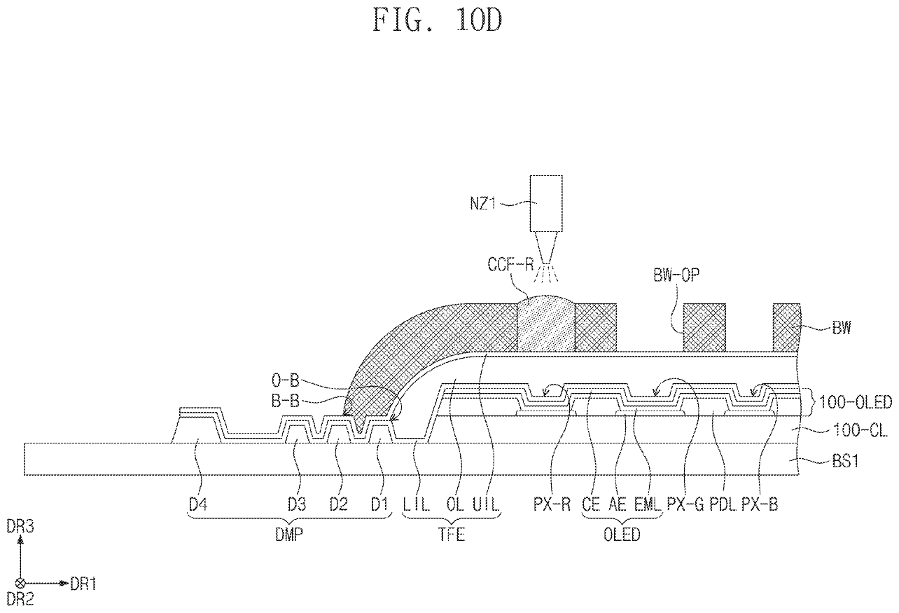

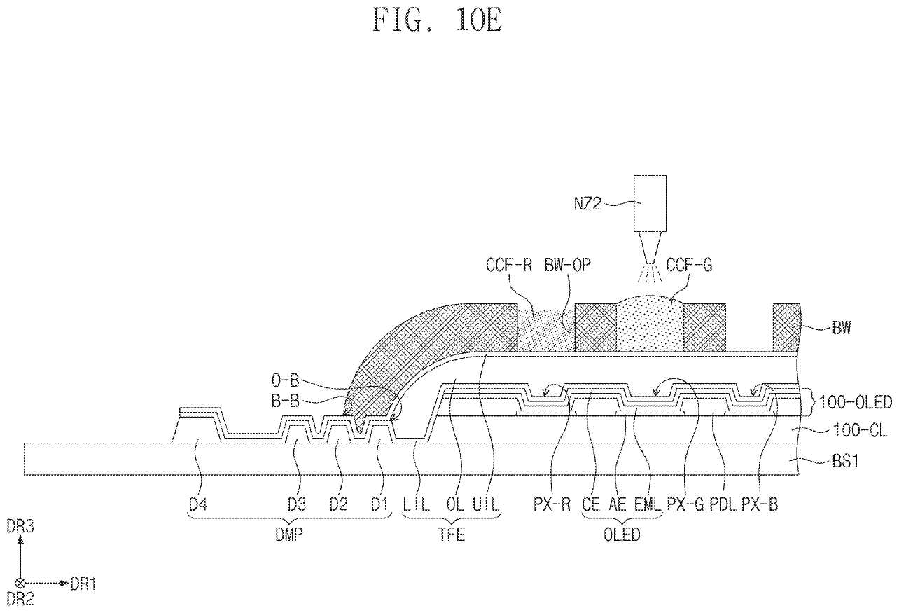

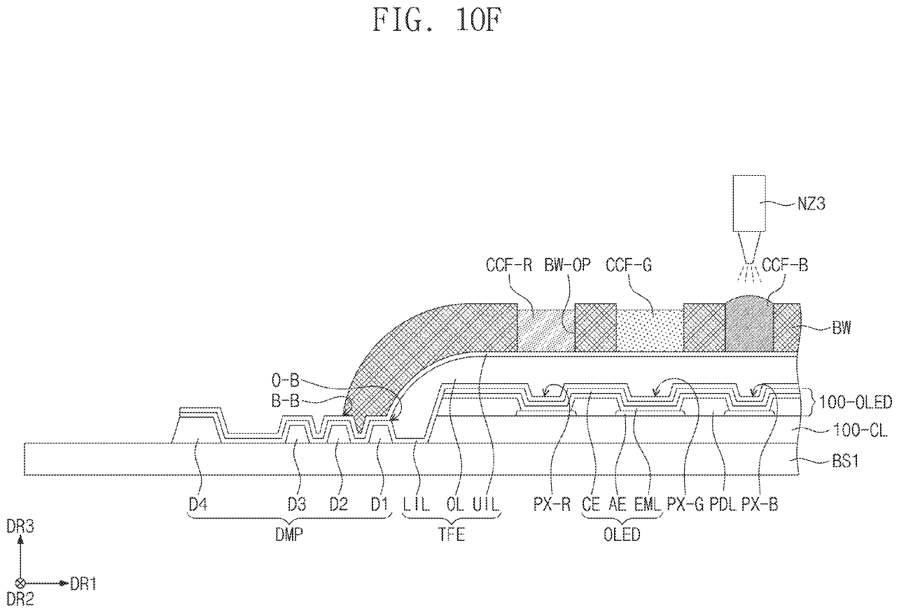

FIG. 9 is a cross-sectional view of a display device according to an embodiment of the present disclosure. The same/similar reference numerals will be assigned to the same/similar components to components described with reference to FIGS. 4 and 5 and thus redundant description will be omitted.

According to an embodiment, a display device DD-D may include the first display substrate 100 and the second display substrate 200. The display device of FIG. 3 may be implemented by the display device DD-D. The first display substrate 100 and the second display substrate 200 may be spaced apart from each other while interposing the sealing member SLM between the first display substrate 100 and the second display substrate 200. The filling material FM may be interposed in the space between the first display substrate 100 and the second display substrate 200.

The first display substrate 100 may include the first base layer BS1, the circuit layer 100-CL, the display device layer 100-OLED, the encapsulation layer TFE, and the light control layer CFL. According to an embodiment, the first display substrate 100 may further include a lower refractive layer LR-D. According to an embodiment, the light control layer CFL may include the split pattern BW, and the light control patterns CCF-R, CCF-G, and CCF-B.

The second display substrate 200 may include the second base layer BS2, the color filters CF-R, CF-G, and CF-B, the upper cover layer CP-U, and the step difference compensating layer CS.

According to an embodiment, most of the lower refractive layer LR-D is overlapped with the display region DA. A portion of the lower refractive layer LR-D may extend to the non-display region NDA. For example, a portion of the lower refractive layer LR-D that overlaps with the display region DA may be larger than the portion that extends to the non-display region NDA. The lower refractive layer LR-D may be directly disposed on the lower cover layer CP-B. For example, the lower refractive layer LR-D may directly contact the lower cover layer CP-B. However, the present disclosure is not limited thereto. For example, when the lower cover layer CP-B is omitted, the lower refractive layer LR-D may directly make contact with the split pattern BW and the light control patterns CCF-R, CCF-G, and CCF-B.

According to an embodiment, the lower refractive layer LR-D is included in the first display substrate 100, and is spaced apart from the non-display region NDA, to prevent moisture from being introduced into the first display substrate 100 and the second display substrate 200 through the lower refractive layer LR-D in a hot and humid environment. Accordingly, the display device DD-D increase in lifespan of the light emitting element OLED (see FIG. 4) may be provided.

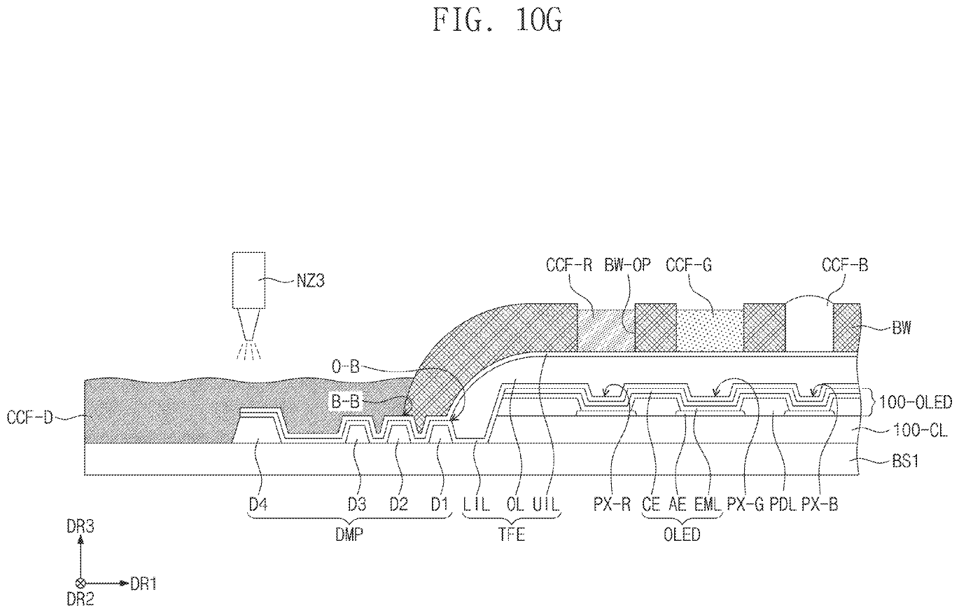

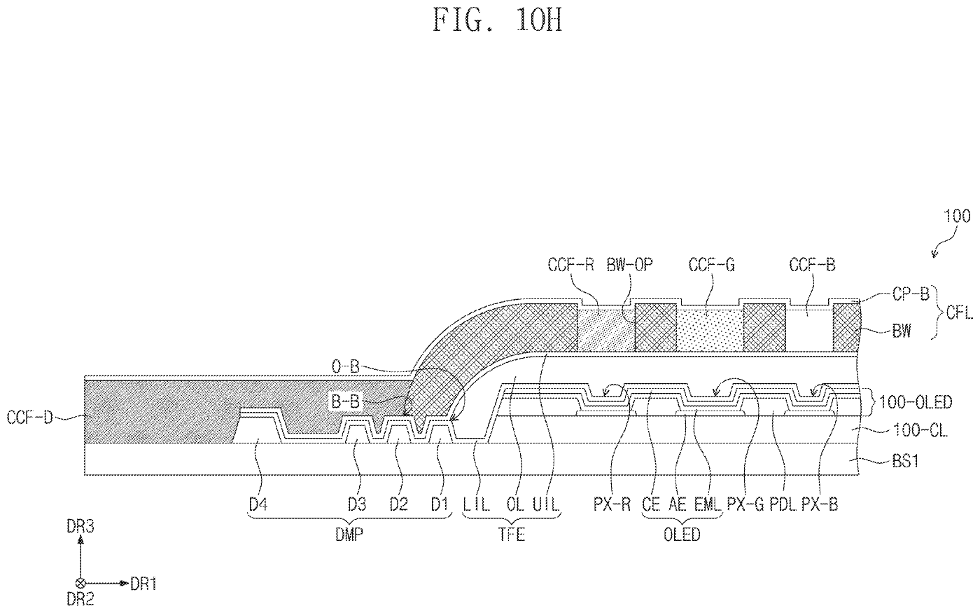

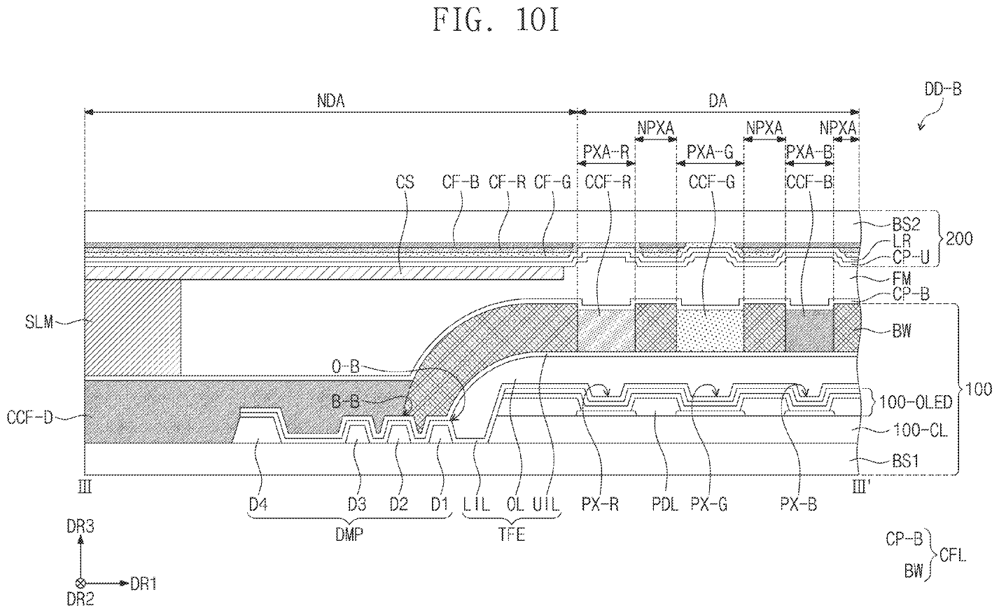

FIGS. 10A to 101 are cross-sectional views illustrating a method for manufacturing a display deice according to an embodiment of the present disclosure. The same/similar reference numerals will be assigned to the same/similar components to components described with reference to FIGS. 4, 5, and 7 and thus redundant description will be omitted. The display device to be formed through the method for manufacturing the display device, which is to be described with reference to FIGS. 10A to 101, may be a display device DD-B described with reference to FIG. 7.

Referring to FIG. 10A, the method for manufacturing the display device according to an embodiment may include providing or forming a working substrate.

In this specification, the working substrate may be defined as being in the form of the first display substrate 100 having the first base layer BS1, the circuit layer 100-CL, the display element layer 100-OLED, and the encapsulation layer TFE, which is described with reference to FIG. 7.

The display device layer 100-OLED may include the light emitting elements OLED including the first electrode AE connected to a transistor formed in the circuit layer 100-CL, the second electrode CE, and the light emitting layer EML. The second electrode CE and the light emitting layer EML may be provided at a common layer to be commonly provided in the light emitting elements OLED.

The first base layer BS1 may include the dam pattern DMP formed at a layer including a material the same as a material of any one of insulating layers included in the circuit layer 100-CL. The dam pattern DMP may include first to fourth dam patterns D1, D2, D3, and D4 disposed in sequence farther away from the pixels PX-R, PX-G, and PX-B.

The encapsulation layer TFE may include the first inorganic layer LIL, the organic layer OL, and the second inorganic layer UIL. The first inorganic layer LIL may cover the pixels PX-R, PX-G, and PX-B.

In an embodiment, during the process of forming the organic layer OL, a solution including an organic material is coated only up to the first dam pattern D1 of the dam pattern DMP. Accordingly, the boundary O-B of the organic layer OL may be determined by the first dam pattern D1 when viewed in a plan view.

The first inorganic layer LIL and the second inorganic layer UIL may be deposited on the entire surface of the first base layer BS1. Accordingly, the first inorganic layer LIL and the second inorganic layer UIL may cover the first to fourth dam patterns D1, D2, D3, and D4. According to an embodiment, a layer deposited on the entire surface of the first base layer BS1 of the circuit layer 100-CL or a layer formed as a common layer of the display device layer 100-OLED may cover at least any one of the first to fourth dam patterns D1, D2, D3, and D4.

Thereafter, referring to FIGS. 10B and 10C, a set of forming the split pattern BW may be included. The split pattern BW may be formed by coating a material including a black coloring agent. The black coloring agent may include a black dye and a black pigment. The black coloring agent may include metal, such as carbon black, and chromium, or an oxide thereof.

In an embodiment, during the step of forming the split pattern BW, the solution including the organic material is coated only up to the second dam pattern D2 of the dam pattern DMP. Accordingly, when viewed in a plan view, the boundary B-B of the split pattern BW may be determined by the second dam pattern D2. According to an embodiment, the second dam pattern D2 defining the boundary B-B of the split pattern BW may be more adjacent or closer to the sealing member SLM than the first dam pattern D1.

Thereafter, a step of forming the openings BW-OP in the split pattern BW may be included. The openings BW-OP may be overlapped with a relevant pixel of the pixels PX-R, PX-G, and PX-B. According to an embodiment, although a right angle is shown between the side surface of the split pattern BW defining the openings BW-OP and the bottom surface of the split pattern BW, the present disclosure is not limited thereto. An acute angle may be formed between the side surface of the split pattern BW and the bottom surface of the split pattern BW. For example, as shown in FIG. 10C, portions of the split pattern BW may be removed to form the openings BW-OP.

Thereafter, referring to FIGS. 10D and 10E, a step of forming the first light control pattern CCF-R in the opening BW-OP (hereinafter, a first opening) overlapped with the first pixel PX-R may be included. The first light control pattern CCF-R may be formed by discharging a material including a base resin and a material including a quantum dot mixed (or dispersed) with the base resin in the ink-jet process through a first nozzle NZ1. For example, the base resin and the quantum dot mixed (or dispersed) with the base resin may be deposited in the first opening BW-OP to form the first light control pattern CCF-R.

Thereafter, a set of forming the second light control pattern CCF-G in the opening BW-OP (hereinafter, a second opening) overlapped with the second pixel PX-G may be included. The second light control pattern CCF-G may be formed by discharging a material including a base resin and a material including a quantum dot mixed (or dispersed) with the base resin in the ink-jet process through a second nozzle NZ2. For example, the base resin and the quantum dot mixed (or dispersed) with the base resin may be deposited in the second opening BW-OP to form the second light control pattern CCF-G.

Thereafter, referring to FIGS. 10F and 10G, a step of forming the first light control pattern CCF-R in the opening BW-OP (hereinafter, a third opening) overlapped with the third pixel PX-B may be included. The third light control pattern CCF-B may be formed by discharging a material including a base resin and a material including scatters mixed (or dispersed) with the base resin in the ink-jet process through the third nozzle NZ3. For example, the base resin and the scatters mixed (or dispersed) with the base resin may be disposed in the third opening BW-OP to form the third light control pattern CCF-B.

As shown in FIG. 10G, the process may further include forming the dummy pattern CCF-D through the third nozzle NZ3. The dummy pattern CCF-D may be spaced apart from the pixels PX-R, PX-G, and PX-B, and formed to cover the dam pattern DMP. When the dummy pattern CCF-D is formed through the ink-jet process, the thickness of the dummy pattern CCF-D in the third direction DR3 may be more easily adjusted.

Thereafter, referring to FIG. 10H, a step of forming the lower cover layer CP-B may be further included. The lower cover layer CP-B may be formed on the entire surface of the first base layer BS1. Accordingly, the lower cover layer CP-B may cover the split pattern BW, the light control patterns CCF-R, CCF-G, and CCF-B, and the dummy pattern CCF-D. In an embodiment, the lower cover layer CP-B includes or is an inorganic material. For example, the lower cover layer CP-B may contact upper surfaces of the split pattern BW, the light control patterns CCF-R, CCF-G, and CCF-B, and the dummy pattern CCF-D.

Thereafter, referring to FIG. 10I, a step of laminating the first display substrate 100 with the second display substrate 200 may be included. The second display substrate 200 may include the second base layer BS2, the color filters CF-R, CF-G, and CF-B, the lower refractive layer LR, the upper cover layer CP-U, and the step difference compensating layer CS.

The first display substrate 100 and the second display substrate 200 may be combined in the vacuum lamination process through the sealing member SLM. In this case, the sealing member SLM may be interposed between the first display substrate 100 and the second display substrate 200 to maintain a specific space. The filling material FM may be filled in the space between the first display substrate 100 and the second display substrate 200.

The sealing member SLM may be overlapped with the dummy pattern CCF-D. According to an embodiment, the dummy pattern CCF-D easily adjustable in thickness is disposed under the sealing member SLM to reduce a dent failure caused in the vacuum lamination process for the first display substrate 100 and the second display substrate 200. When the distance between the first display substrate 100 and the second display substrate 200 is uniformly maintained by using the dummy pattern CCF-D in the vacuum lamination process of the first display substrate 100 and the second display substrate 200, the resilient force of the first base layer BS1 and/or the second base layer BS2 made due to the step difference between the first display substrate 100 and the second display substrate 200 may be reduced/canceled.

According to an embodiment of the present disclosure, when the upper substrate and the lower substrate are combined with each other, as the step difference of components included in the upper substrate and the lower substrate is compensated, the dent failure may be reduced. Accordingly, the display device reduced in defective ratio may be provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a first display substrate including a first base layer comprising a display region and a non-display region adjacent to the display region;
a second display substrate including a second base layer comprising pixel regions overlapped with the display region and a peripheral region adjacent to the pixel regions, and color filters disposed on the second base layer, and spaced apart from the first display substrate; and
a sealing member interposed between the first display substrate and the second display substrate and overlapped with the non-display region,
wherein the first display substrate comprises:
light emitting elements overlapped with the pixel regions, respectively;
an encapsulation layer to cover the light emitting elements;
a split pattern including openings overlapped with the pixel regions, respectively, and disposed on the encapsulation layer; and
light control patterns disposed in the openings, and
wherein an end portion of an organic layer of the encapsulation layer overlapped with the non-display region is covered by the split pattern.

2. The display device of claim 1, wherein the second display substrate further comprises:
a lower refractive layer to cover the color filters;
an upper cover layer to cover the lower refractive layer; and
a step difference compensating layer that covers the upper cover layer and is overlapped with the non-display region, and
wherein the sealing member contacts the step difference compensating layer and the first display substrate.

3. The display device of claim 1, wherein the second display substrate further comprises:
an upper cover layer to cover the color filters; and
a step difference compensating layer that covers the upper cover layer and is overlapped with the non-display region, and
wherein the sealing member contacts the step difference compensating layer and the first display substrate.

4. The display device of claim 1, wherein the first display substrate further comprises:
a dummy pattern disposed in the non-display region,
wherein a material of the dummy pattern is the same as a material of one of the light control patterns, and
wherein the sealing member is interposed between the dummy pattern and the second display substrate.

5. The display device of claim 1, wherein the split pattern further comprises:
a first part disposed in the display region and a second part disposed in the non-display region and extending from the first part, and
wherein the sealing member is interposed between the second part and the second display substrate.

6. The display device of claim 5, wherein the second part comprises:
at least one pattern hole formed through the split pattern while extending from a top surface of the split pattern and a bottom surface of the split pattern, and
wherein the sealing member is disposed inside the at least one pattern hole.

7. The display device of claim 1, wherein the first display substrate further comprises:
dam patterns disposed on the first base layer and overlapped with the non-display region,
wherein a boundary of the organic layer is defined by a first one of the dam patterns and a boundary of the split pattern is defined by a second other one of the dam patterns, and
wherein the second dam pattern is more closer to the sealing member than the first dam pattern.

8. The display device of claim 7, wherein each of the dam patterns has a closed-line shape to surround the display region.

9. The display device of claim 7, wherein the organic layer is disposed between a first inorganic layer of the encapsulation layer and a second inorganic layer of the encapsulation layer, the first inorganic layer and the second inorganic layer contact each other in the non-display region and cover at least one of the dam patterns.

10. The display device of claim 1, wherein the first display substrate and the second display substrate are spaced apart from each other while interposing a cell gap between the first display substrate and the second display substrate.

11. The display device of claim 10, further comprising:
a filling material including an organic material that fills the cell gap.

12. The display device of claim 1, wherein the color filters comprise:
a first color filter, a second color filter, and a third color filter, and
wherein at least two color filters of the first color filter, the second color filter, and the third color filter are overlapped with each other in the peripheral region.

13. The display device of claim 12, wherein the light emitting elements comprises:
a first light emitting element, a second light emitting element, and a third light emitting element,
wherein each of the first light emitting element, the second light emitting element, and the third light emitting element generates a blue source light,
wherein first and second filter openings are defined in the third color filter to correspond to first and second pixel regions, respectively,
wherein the third color filter is overlapped with the third pixel region, and
wherein the third color filter is a blue color filter.

14. The display device of claim 13, wherein the light control patterns comprise:
a first light control pattern, a second light control pattern, and a third light control pattern, and
wherein each of the first light control pattern and the second light control pattern include a base resin and a quantum dot.

15. The display device of claim 14, wherein the third light control pattern includes a base resin and a scatterer.

16. The display device of claim 1, wherein the first display substrate further comprises:
an upper cover layer configured to cover the split pattern and the light control patterns, and including an inorganic material.

17. A method for manufacturing a display device, the method comprising:
forming a working substrate including a first base layer including a display region and a non-display region, a circuit layer disposed on the first base layer and having a transistor, a display element layer including a light emitting element disposed on the circuit layer and connected to the transistor, and an encapsulation layer to cover the display element layer;
forming a split pattern overlapped with the display region on the working substrate to include a first opening, a second opening, and a third opening;
forming a first light control pattern in the first opening;
forming a second light control pattern in the second opening;
forming a third light control pattern in the third opening; and
forming a dummy pattern on the first base layer overlapped with the non-display region,
wherein the third light control pattern and the dummy pattern include the same material.

18. The method of claim 17, further comprising:
forming a first display substrate by forming a lower cover layer to cover the split pattern, the first control pattern, the second control pattern, the third control pattern, and the dummy pattern; and
laminating, with the first display substrate, a second display substrate including a second base layer, color filters disposed on a bottom surface of the second base layer, a lower refractive layer to cover the color filters, an upper cover layer to cover the lower refractive layer, and a step difference compensating layer that covers the upper cover layer and is overlapped with the non-display region.

19. The method of claim 18, wherein the first display substrate and the second display substrate are combined with each other through a sealing member in a vacuum-lamination process, while interposing a cell gap between the first display substrate and the second display substrate.

20. The method of claim 19, wherein the sealing member is interposed between the step difference compensating layer and the dummy pattern.
